(19) United States
(12) Patent Application Publication
(10) Pub. No.: US 2020/0201178 A1
(43) Pub. Date: Jun. 25, 2020

(54) PHOTOCURABLE COMPOSITION HAVING LOW SHRINKAGE AFTER CURING

(71) Applicant: CANON KABUSHIKI KAISHA, Tokyo (JP)

(72) Inventors: Fen Wan, Austin, TX (US); Weijun Liu, Cedar Park, TX (US)

(21) Appl. No.: 16/227,981

(22) Filed: Dec. 20, 2018

(51) Int. Cl. G03F 7/027; G03F 7/00; C08F 2/48; C08K 5/23; H05K 3/06

(52) U.S. Cl. CPC G03F 7/027; G03F 7/0002; H05K 2203/0502; C08K 5/23; H05K 3/061; C08F 2/48

(57) ABSTRACT

A photocurable composition can comprise a polymerizable material and a shrinkage compensating agent (SCA), wherein the photocurable composition may be adapted that a linear shrinkage of the photocurable composition after curing is not greater than 3 percent. The shrinkage compensating agent can be a compound comprising a functional group which releases a gas if subjected to UV radiation or heat. The released gas can form a fine pore structure within the cured photocurable composition and may thereby compensate shrinkage of the photocurable composition during curing.

### FIELD OF THE DISCLOSURE

The present disclosure relates to a photocurable composition comprising a shrinkage compensating agent (SCA), particularly a UV curable resist for nanoimprinting and inkjet adaptive planarization.

### RELATED ART

Nanoimprint lithography (NIL) and inkjet adaptive planarization (IAP) both employ flowable liquids as photocurable compositions, also called resists, which can be cured by UV- or heat treatment. During curing of the resist, an unwanted side effect is the shrinkage of the material, which is typically in a range of 4% to 20%.

There exists a need to reduce or eliminate the shrinkage of the resist during curing.

### SUMMARY

In one embodiment, a photocurable composition can comprise a polymerizable material and a shrinkage compensating agent (SCA), wherein the photocurable composition can be adapted that a linear shrinkage of the resist after curing may be not greater than 3%.

According to one aspect, the SCA contained in the photocurable composition can release a gas if exposed to UV radiation or heat.

In one aspect, the gas released by the SCA can be nitrogen, carbon dioxide, or oxygen.

In a particular aspect, the SCA can be a compound comprising an azo-group, or a diazo-group, or an azido-group, or a sulfohydrazide group, or a hydrazo group, or a nitrobenzyl carbamate group, or a benzoin carbamate group, or a diazomethanesulfonic acid group.

In a certain aspect, the SCA can include 1,1′-azobis(1-cyclohexanecarbonitrile); 2,2′-azobisisobutyronitril (AIBN); dimethyl 2,2′-azobis-isobutyrate; 2,2′-azobis(2-methyl butyronitrile; 2,2′-azobis(4-methoxy-2,4-dimethylvaleronitrile); 2,2′-azobis (2,4-dimethylvaleronitrile); or any combination thereof.

In another aspect, an amount of the SCA can be at least 0.1 wt % and not greater than 5 wt % based on the total weight of the resist.

In one aspect, the resist can be adapted that the linear shrinkage after curing may be not greater than 2% and not less than −2%.

In yet a further aspect, the photocurable composition can comprise a crosslinking agent.

In one aspect, the polymerizable material of the photocurable composition can be a monomer, an oligomer, or a polymer. In a particular aspect, the polymerizable material can be a UV curable acrylic polymer or co-polymer.

In a further aspect, the SCA contained in the photocurable composition can be also a photo-initiator and the resist may not comprise a further photo-initiator in addition to the SCA.

According to another embodiment, a method of forming a cured resist can comprise: preparing a resist in form of a liquid mixture comprising a polymerizable material and a shrinkage compensating agent (SCA); forming a layer from the resist on a substrate; curing the resist by polymerizing the polymerizable material to form a cured resist; and initiating the SCA to releasing a gas; wherein a linear shrinkage of the cured resist in comparison to the resist before curing may be not greater than 3%.

In one aspect, the resist of the method can further comprise a cross-linking agent.

In another aspect, releasing the gas from the SCA can be conducted during curing of the resist.

In a further aspect, releasing of the gas by the SCA can be conducted before curing of the resist.

In yet a further aspect of the method, the linear shrinkage of the cured resist in comparison to the resist before curing may be not greater than 2% and not less than −2%.

In one aspect, the SCA of the method can be a compound comprising an azo-group in an amount of at least 0.1 wt % and not greater than 3 wt % based on a total weight of the resist.

In another aspect, curing of the resist and releasing gas by the SCA during the method can be conducted under UV radiation.

In one aspect, the SCA of the method can further function as a photo-initiator for curing the resist.

In another aspect, the polymerizable material contained in the resist of the method can be a UV curable acrylic polymer or co-polymer.

In another embodiment, a method for forming a photo-cured product pattern can comprise forming a solid adhesion layer; applying the photocurable composition described above onto the substrate, wherein the photocurable composition is overlying the adhesion layer; bringing the photocurable composition into contact with a mold having an original pattern to be transferred; irradiating the photocurable composition with light to form a photo-cured product; and removing the mold from the photo-cured product.

In yet a further embodiment, a method for manufacturing a circuit board can comprise forming a photo-cured product pattern as described above; working the substrate by etching or ion implantation using the patterned film as a mask; and forming an electronic member. In one aspect, the circuit board can be a semiconductor element.

### BRIEF DESCRIPTION OF THE DRAWINGS

Embodiments are illustrated by way of example and are not limited in the accompanying figures.

FIG. 1 includes an illustration of a resist on a substrate and subjected to UV curing according to one embodiment.

FIG. 2 includes a graph showing resist shrinkage in relation to time during curing according to embodiments.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a photocurable composition comprising a polymerizable material and a shrinkage compensating agent (SCA). The photocurable composition can be adapted that a linear shrinkage of the photocurable composition after curing may be not greater than 3 percent. As used herein, the term photocurable composition relates to a curable liquid composition which can be suitable for nanoimprint lithography or inkjet adaptive planarization. In a particular aspect, the photocurable composition can be a resist. If not indicated otherwise, synonymous expression for the term resist used herein are resist composition, liquid resist or curable resist.

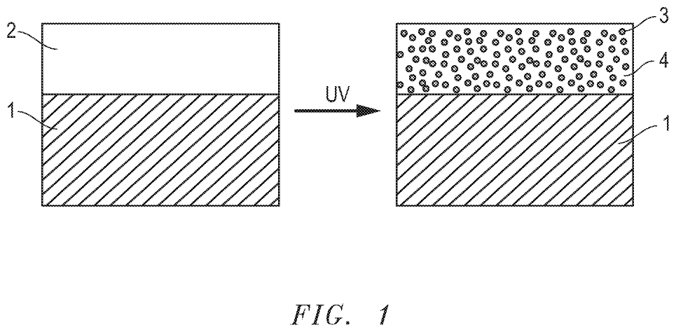

In one embodiment, the shrinkage compensating agent (SCA) contained in the photocurable composition can be a compound which can release a gas if exposed to UV radiation and/or heat treatment. As illustrated in the embodiment shown in FIG. 1, the photocurable composition in form of a liquid resist (2) can be applied as an even layer onto a substrate (1), e.g., by spin-coating or by ink-jetting. By applying UV-radiation to the liquid resist layer (2), a gas can be released from the SCA while the resist concurrently undergoes curing. By coordinating the type, amount and dispersion of the SCA within the resist composition, the gas released by the SCA can form evenly distributed pores (3) within the cured resist (4) and can compensate unwanted shrinkage during curing.

In one aspect, the pores formed by the released gas can be very small, such as not greater than 2 nm, or not greater than 1 nm, or not greater than 0.8 nm, or not greater than 0.5 nm. Not being bound to theory, it is assumed that the fine pore structure formed in the photocurable composition may compensate shrinkage of the liquid resist during curing. It has been surprisingly observed that a photocurable composition containing a dispersed SCA in a well-adjusted amount can develop a very fine and evenly distributed pore structure and thereby compensate shrinkage of the photocurable composition material during curing, while mechanical properties, for example, modulus of elasticity, Young's modulus, and elongation can be maintained to a large extent.

The gas released by the shrinkage compensating agent can be nitrogen, carbon dioxide, carbon monoxide, or oxygen. In a particular aspect, the gas may be nitrogen or carbon dioxide. Compounds suitable as shrinkage compensating agent in the context of the present disclosure can be compounds comprising a functional group which can be transformed into a gas and released if subjected to UV radiation and/or heat. Such functional groups can be, for example, an azo-group, a diazo-group, an azido-group, a sulfohydrazide group, a hydrazo group, a nitrobenzyl carbamate group, a benzoin carbamate group, or a diazomethanesulfonic acid group. Representative compounds containing such functional groups can be diazonium salts, diazonaphthoquinone, or benzene sulfonylhydrazide. In a particular aspect, the shrinkage compensating agent can be a bis-azo compound, such as 1,1′-azobis(1-cyclohexanecarbonitrile); or 2,2′-azobisisobutyronitril (AIBN); or dimethyl 2,2′-azobis-isobutyrate; or 2,2′-azobis(2-methyl butyronitrile; or 2,2′-azobis(4-methoxy-2,4-dimethylvaleronitrile); or 2,2′-azobis (2,4-dimethylvaleronitrile)azobisisobutyronitrile; or 2,2′-azobis-(N-butyl-2-methylpropionamide; or 1,2-naphthoquinonediazide-5-sulfonic acid ester; or any combination thereof.

In a certain embodiment, the shrinkage compensating agent (SCA) can also function as a photo-initiator for polymerizing the polymerizable compound. In this case, curing of the photocurable composition and releasing of the gas by the SCA may happen at the same time.

In another aspect, when the SCA does not function as a photo-initiator, the release of the gas by the SCA can be also initiated before the curing of the photocurable composition.

The amount of the shrinkage compensating agent (SCA) in the photocurable composition can be at least 0.1 wt % based on the total weight of the resist, such as at least 0.3 wt %, at least 0.5 wt %, at least 0.8 wt %, at least 1.0 wt %, at least 1.5 wt %, at least 2.0 wt % or at least 2.5 wt %. In another embodiment, the SCA may be not greater than 3.5 wt %, such as not greater than 3.0 wt %, not greater than 2.8 wt %, not greater than 2.5 wt %, not greater than 2.2 wt %, not greater than 2.0 wt %, or not greater than 1.8 wt % based on a total weight of the resist. The amount of the SCA can be a value between any of the minimum and maximum values noted above, such as from 0.1 wt % to 3.5 wt %, from 0.5 wt % to 3.0 wt %, or from 0.8 wt % to 2.5 wt % based on the total weight of the photocurable composition.

As used herein, the linear shrinkage (SL) is calculated by equation (1): SL=(L_{R}−L_{CR}/L_{R})×100% (1), wherein L_{R} is the thickness of the photocurable composition layer before curing and L_{CR} is the thickness of the cured photocurable composition layer.

In a certain embodiment, the shrinking compensating agent (SCA) can completely compensate shrinkage of the resist during curing. In another certain embodiment, the SCA may cause an increase (expansion) of the volume of the resist after curing. In the embodiment wherein the cured resist is expanded and has a larger thickness than before curing, the result of the linear shrinkage according to equation (1) is herein expressed as a negative value.

In a particular aspect, a linear shrinkage of an SCA containing resist after curing can be not greater than 3%, such as not greater than 2.5%, not greater than 2.0%, not greater than 1.5%, not greater than 1.0%, not greater than 0.5%, not greater than 0.2%, or not greater than 0.1%. In a further particular aspect, a linear shrinkage may have a negative value (corresponding to an expansion of the resist after curing) of not lower than −3%, such as not lower than −2.5%, not lower than −2.0%, not lower than −1.5%, not lower than −1.0%, not lower than −0.8%, or not lower than −0.5%. The linear shrinkage can be a value within any of the minimum and maximum values noted above, such as from −3% to 3%, from −2% to 2%, from −1% to 1%, or from −0.5% to 0.5%.

The polymerizable compound of the photocurable composition can comprise at least one functional group and can include a monomer, an oligomer, a polymer, or any combination thereof. In one aspect, the polymerizable compound can be cross-linked by a cross-linking agent contained within the resist composition. In another aspect, the polymerizable compound can polymerize with itself without the help of a cross-linking agent. The polymerization reactions can be initiated by a photo-initiator or catalyst.

Non-limiting examples of reactive functional groups of the polymerizable compound can be a hydroxyl group, a carboxyl group, an amino group, an imino group, a (meth)acryloyl group, an epoxy group, an oxetanyl group, or a maleimide group. Such functional groups can be included, e.g., in alkyd resins, polyester resins, acrylic resins, acrylic-alkyd hybrids, acrylic-polyester hybrids, substituted polyether polymers, substituted polyolefin polymers, polyurethane polymers or co-polymers thereof. In a certain embodiment, the polymerizable compound can include an acrylate monomer or oligomer. Other non-limiting examples of polymerizable compounds can include 2-ethyl hexyl acrylate, butyl acrylate, ethyl acrylate, methyl acrylate, benzyl acrylate, isobornyl acrylate, phenol (EO) acrylate, stearyl acrylate, or any combination thereof.

In further embodiments, the polymerizable compound can be a single monomer, or an oligomer, or a mixture of two or three or four or more monomers.

The amount of polymerizable compound in the photocurable composition can be at least 5 wt % based on the total weight of resist, such as at least 10 wt %, at least 15 wt %, or at least 20 wt %. In another aspect, the amount of polymerizable compound may be not greater than 95 wt %, such as not greater than 85 wt %, not greater than 80 wt %, not greater than 70 wt %, not greater than 60 wt %, not greater than 50 wt %, not greater than 40 wt %, not greater than 35 wt %, not greater than 30 wt %, not greater than 25 wt %, or not greater than 22 wt % based on the total weight of the resist. The amount of polymerizable compound can be a value between any of the minimum and maximum values noted above. In a particular aspect, the amount of polymerizable compound can be at least 20 wt % and not greater than 80 wt %.

The photocurable composition of the present disclosure can further include a cross-linking agent. Non-limiting examples of suitable cross-linking agents can be difunctional monomers such as 1,6-hexanediol diacrylate, dipropylene glycol diacrylate, neopentyl glycol diacrylate, and trifunctional monomers such as trimethylolpropane triacrylate, glycerine (PO)3 triacrylate, pentaerythritol triacrylate, or any combination thereof.

The amount of the cross-linking agent contained in the photocurable composition can be at least 10 wt %, such as at least 15 wt %, at least 20 wt %, or at least 25 wt % based on a total weight of the resist. In another aspect, the amount of the cross-linking agent may not be greater than 95 wt %, such as not greater than 80 wt %, not greater than 70 wt %, or not greater than 60 wt %, or not greater than 55 wt %. The amount of the cross-linking agent may be a value within any of the minimum and maximum values noted above. In a particular aspect, the cross-linking agent can be at least 10 wt % and not greater than 55 wt % based on the total weight of the photocurable composition.

In another embodiment, the resist of the present disclosure can contain in addition to the SCA a photo-initiator. A photo-initiator can be added particularly in embodiments wherein the SCA itself does not function as a photo-initiator or may not be efficient enough. This can be, for example, if the polymerizable material requires a specific photo-initiator or a higher amount of photo-initiator than the adjusted amount of SCA than to compensate shrinkage.

In yet a further embodiment, the photocurable composition can contain a catalyst which can catalyze the polymerization of the polymerizable compound. In one aspect, the catalyst can catalyze the cross-linking reaction between polymerizable compound and cross-linking agent at elevated temperatures. The selection of the catalyst may depend on the type of polymerizable compound and/or the type of cross-linking agents and is not limited to any specific type of catalyst.

The photocurable composition can further contain one or more additives. Non-limiting examples of optional additives can be stabilizers, dispersants, solvents, surfactants, inhibitors or any combination thereof.

In a further embodiment, the present disclosure is directed to a method of forming a photocurable composition, for example, a cured resist. In one aspect, the method can comprise preparing a resist in form of a liquid mixture comprising a polymerizable material and a shrinkage compensating agent (SCA). In one aspect, to insure an even and well dispersion of the SCA within the resist composition, mixing can be conducted by roller mixing, sonication, or magnet stirring.

The liquid resist can be applied on the substrate in form of a thin layer. In a particular embodiment, the liquid resist can be applied by ink-jetting drops on the substrate.

To insure the forming of a high quality resist layer, the resist may have a desired low viscosity. In one embodiment, the viscosity of the resist composition can be at least 3 cP, such as at least 4 cP, at least 5 cP, at least 7 cP, or at least 10 cP. In another embodiment, the viscosity can be not greater than 25 cP, such as not greater than 20 cP, not greater than 15 cP, or not greater than 12 cP. The viscosity of the resist composition can be a value between any of the minimum and maximum values noted above. In a particular embodiment, the viscosity of the liquid resist can be at least 4 cP and not greater than 15 cP.

The thickness of the resist layer formed on the substrate can be at least 5 nm, such as at least 10 nm, at least 20 nm, or at least 30 nm. In another aspect, the thickness may be not greater than 250 nm, such as not greater than 200 nm, not greater than 150 nm, or not greater than 100 nm.

In certain embodiments, the substrate can contain on its surface a thin adhesion layer onto which the resist is applied. The adhesion layer may provide enhanced adhesion of the resist to the substrate, specifically after curing of the resist.

After forming of the resist layer, the resist layer can be subjected to conditions under which the resist can cure, i.e., wherein the polymerizable compound can react with a cross-linking agent contained in the resist or polymerize by itself and thereby solidifying the resist. Conditions under which the resist can be cured may be exposure to UV-radiation and/or to heat.

In a particular embodiment, the curing of the resist can be conducted concurrently with initiating gas release of the shrinkage compensating agent. In one aspect, this can be coordinated if the SCA can also function as a photo-initiator to generate radicals to initiate the resist polymerization when releasing the gas.

In another aspect, the SCA can be controlled to release a gas before the curing of the resist. In this embodiment, the resist may contain a further photo-initiator or catalyst which can initiate/activate the curing reactions after forming of the gas. Moreover, it can be of advantage if the gas can be dissolved to a certain degree in the liquid resist composition.

As further demonstrated in the examples, it has been surprisingly discovered that by employing a shrinkage compensating agent (SCA) in a resist composition and fine tuning the amount and distribution of the SCA within the resist, the linear shrinkage of the resist after curing can be reduced to a large extent. In contrast, typical resist compositions, which do not include an SCA, have a shrinkage after curing between 3 and 7 percent.

In another embodiment, the present disclosure is directed to a method of forming a photo-cured product pattern. The method can comprise forming an adhesion layer by applying the liquid adhesion composition onto a substrate and curing the liquid adhesion composition. Thereafter, the photocurable composition (for example, a liquid resist) described above can be applied on top of the adhesion layer and a mold may be brought in contact with the photocurable composition such that the photocurable composition can fill the mold. The mold may contain an original pattern to be transferred, hereinafter also called relief pattern. After the photocurable composition has filled the mold, the photocurable composition can be radiated with light, for example, UV light, to form a photo-cured product. After curing of the photocurable composition, the mold can be removed from the photo-cured product.

In the above-described process, the photo-cured product pattern can have a desired relief pattern (derived from the relief pattern of the mold) in a desired position, and thus, an article having the photo-cured product pattern can be obtained.

The photo-cured product pattern may be used as an interlayer insulating film of a semiconductor device, such as LSI, system LSI, DRAM, SDRAM, RDRAM, or D-RDRAM, or as a resist film used in a semiconductor manufacturing process.

In the embodiment wherein the photo-cured product pattern is used as a resist film, the photo-cured product pattern can function as an etching mask. In a particular aspect, the substrate can contain electronic members and a circuit structure can be formed on the substrate according to the profile of the photo-cured product pattern. Thus, a circuit board used in a semiconductor device or the like can be produced. The resulting circuit board may be connected to a control mechanism for the circuit board for producing an electronic component of a display, a camera, a medical apparatus, or any other apparatus.

Similarly, the photo-cured product pattern may be used as a resist film for etching and/or ion implantation in a process for manufacturing an optical component or a device component, such as a flow channel structure of microfluidics and a patterned medium structure.

Although etching and ion implantation have been described in embodiments as the method for etching the substrate using the photo-cured product pattern as a mask, the method is not limited to these. For example, plating may be performed on the substrate provided with the photo-cured product pattern. In a process for manufacturing a circuit-including substrate or an electronic component, the photo-cured product pattern may be finally removed from the substrate, or may be left as a member of a device.

### EXAMPLES

The following non-limiting examples illustrate the concepts as described herein.

### Example 1

A liquid resist composition (S1) was prepared by mixing 105 g of a mono- and difunctional acrylate-based resist composition (80 parts monofunctional acrylate, 30 parts difunctional acrylate, 4 parts surfactants, 2 parts photoinitiator Irgacure 651 from BASF and 1 part photoinitiator Irgacure 907 from BASF) with 3 g of azo-group containing compound 1,1′-Azobis(1-cyclohexanecarbonitrile) (V-40 from Aldrich) as shrinkage compensating agent and photo-initiator (SCA) in a roller mixer for about 20 minutes. After mixing, the resist had a viscosity of 7 cP at room temperature.

Shrinkage Measurements:

Shrinkage measurements were performed with an Anton Paar MCR-301 rheometer coupled to an UV curing system and heater. For the testing, a drop of 7 μl of the resist composition was added onto a plate and a temperature control hood was released to insulate the drop and the measuring unit. The amount of resist was designed to obtain a thickness (hereinafter also called height) of the resist layer of slightly higher than 0.1 mm. By pre-setting the target height to 0.1 mm, the measuring unit moved down to the set value, causing extra amount of resist flowing off the plate. This insured that the exact height of the liquid resist was 0.1 mm before curing. Thereafter, the resist was cured with a UV power of 100 mW/cm² at 365 nm for 600 seconds. After curing of the resist, the height was measured again and the linear shrinkage calculated according to equation (1). The measured result was a negative shrinkage of −5%, which means that the volume of the resist expanded during curing.

A comparable resist composition (C1) was prepared exactly the same way as sample S1, except that it did not contain the shrinkage compensating agent (SCA). The curing of the resist and measurement of the change in height of the resist before and after curing was conducted according to the same procedure as for sample S1. The obtained linear shrinkage for resist composition C1 was 3.5%.

A summary of the test results is also shown in Table 1. It can be seen that 1,1′-Azobis(1-cyclohexanecarbonitrile) reacted as expected by releasing nitrogen and could not only compensate shrinkage of the resist but even lead to a 5% expansion (expressed as −5% shrinkage). In contrast, comparative sample C1, which employed only photo-initiators which do not release a gas during initiation, resulted in the known shrinkage effect.

TABLE 1

| Sample | Amount of SCA [wt %] | Shrinkage [%] |
|---|---|---|
| S1 | 30 | −5 |
| C1 | 0 | +3.5 |

### Example 2

A series of resist compositions were prepared the same way as described in Example 1, except that the concentration of bis-azo-compound V-40 was varied. Furthermore, a comparative example C1 was prepared and tested using a photoinitiator which does not release a gas, i.e., Irgacure 907.

Table 2 provides a summary of the experiments. It can be seen that with increasing amount of the bis-azo compound (i.e., shrinking compensating agent SCA), the amount of shrinkage could be reduced and shrinkage could be even converted to an expansion of the resist after curing (expressed as negative shrinkage), see sample S3.

TABLE 2

| Sample | Amount of SCA [wt %] | Shrinkage [%] |
|---|---|---|
| C1 | 0 | 3.50 |
| S1 | 1% | 2.50 |
| S2 | 2% | 1.20 |
| S3 | 3% | −1.00 |

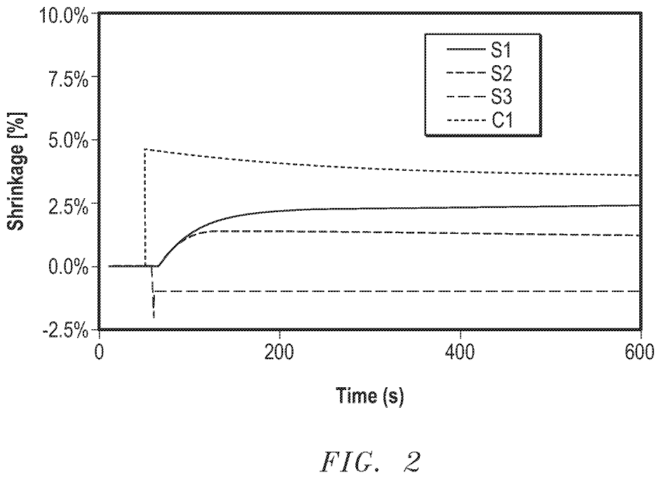

The shrinkage of resist samples C1 and S1 to S3 in dependency to the curing time is illustrated in FIG. 2. It can be seen that sample S3 with the shrinkage of −1.0% reaches very fast a plateau value which does not further change with time. In comparison, the larger the shrinkage of the resist during curing, the longer it takes for the cured resist to reach a final plateau value.

The experiments demonstrate that by carefully tuning the amount of shrinkage compensating agent and evenly integrating it in the resist composition, it is possible to achieve curing of a resist with very minor shrinkage in a range of ±2%.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material and a shrinkage compensating agent (SCA),
wherein the photocurable composition is adapted that a linear shrinkage of the photocurable composition after curing is not greater than 3 percent.

2. The photocurable composition of claim 1, wherein the SCA is a compound comprising a functional group which releases a gas if subjected to UV radiation or heat.

3. The photocurable composition of claim 2, wherein the gas is nitrogen, carbon dioxide, or oxygen.

4. The photocurable composition of claim 1, wherein the SCA is a compound comprising an azo-group, or a diazo-group, or an azido-group, or a sulfohydrazide group, or a hydrazo group, or a nitrobenzyl carbamate group, or a benzoin carbamate group, or a diazomethanesulfonic acid group.

5. The photocurable composition of claim 4, wherein the SCA includes 1,1′-azobis(1-cyclohexanecarbonitrile); 2,2′-azobisisobutyronitril (AIBN); dimethyl 2,2′-azobis-isobutyrate; 2,2′-azobis(2-methyl butyronitrile; 2,2′-azobis(4-methoxy-2,4-dimethylvaleronitrile); 2,2′-azobis (2,4-dimethylvaleronitrile), or any combination thereof.

6. The photocurable composition of claim 1, wherein an amount of the SCA is at least 0.1 wt % and not greater than 5 wt % based on the total weight of the photocurable composition.

7. The photocurable composition of claim 1, wherein the photocurable composition is adapted that a linear shrinkage is not greater than 2% and not less than −2%.

8. The photocurable composition of claim 1, wherein the SCA is also a photo-initiator and the photocurable composition does not comprise a further photo-initiator in addition to the SCA.

9. A method of forming a cured resist, comprising:
preparing a resist in form of a liquid mixture comprising a polymerizable material and a shrinkage compensating agent (SCA);
forming a layer from the resist on a substrate;
curing the resist by polymerizing the polymerizable material to form a cured resist; and
initiating the SCA to releasing a gas;
wherein a linear shrinkage of the cured resist in comparison to the resist before curing is not greater than 3%.

10. The method of claim 9, wherein the resist further comprises a cross-linking agent.

11. The method of claim 9, wherein releasing of the gas by the SCA is conducted during curing of the resist.

12. The method of claim 9, wherein releasing of the gas by the SCA is conducted before curing of the resist.

13. The method of claim 9, wherein the linear shrinkage of the cured resist in comparison to the resist before curing is not greater than 2% and not less than −2%.

14. The method of claim 9, wherein the SCA is a compound comprising an azo-group in an amount of not greater then 3wt % based on a total weight of the resist.

15. The method of claim 9, wherein curing of the resist and releasing gas by the SCA is conducted under UV radiation.

16. The method of claim 9, wherein the SCA further functions as a photo-initiator for curing the resist.

17. The method of claim 9, wherein the polymerizable material is a UV curable acrylic polymer or co-polymer.

18. A method of forming a photo-cured product pattern, comprising:
forming an adhesion layer onto a substrate;
applying the photocurable composition of claim 1 onto the substrate, wherein the photocurable composition is overlying the adhesion layer;
bringing the photocurable composition into contact with a mold having an original pattern to be transferred;
irradiating the photocurable composition with light to form a photo-cured product; and
removing the mold from the photo-cured product.

19. A method for manufacturing a circuit board, the method comprising:
forming a patterned film by the method as set forth in claim 18;
working the substrate by etching and/or ion implantation using the patterned film as a mask; and
forming an electronic member.

20. The method according to claim 19, wherein the circuit board is a semiconductor element.
